(19) United States
(12) Patent Application Publication
(10) Pub. No.: US 2026/0136967 A1
(43) Pub. Date: May 14, 2026

(54) PACKAGE SUBSTRATE, SEMICONDUCTOR PACKAGE INCLUDING THE SAME, AND MANUFACTURING METHOD OF THE SEMICONDUCTOR PACKAGE

(71) Applicant: SAMSUNG ELECTRONICS CO., LTD., Suwon-si (KR)

(72) Inventor: Seungjin OH, Suwon-si (KR)

(73) Assignee: SAMSUNG ELECTRONICS CO., LTD., Suwon-si (KR)

(21) Appl. No.: 19/221,980

(22) Filed: May 29, 2025

(30) Foreign Application Priority Data
Nov. 8, 2024 (KR) 10-2024-0158289

(51) Int. Cl. H01L 23/498; H01L 23/00; H01L 23/31

(52) U.S. Cl. CPC H10W 70/65; H10W 70/635; H10W 74/117; H10W 90/701; H10W 90/724

(57) ABSTRACT

A package substrate may include a base layer including a first surface and a second surface opposite thereto, a distribution structure in the base layer, bump pads connected to the distribution structure and on the first surface of the base layer, connection terminals attached to the first bump pads and having a melting point at a first temperature, and metal protection layers on surfaces of the connection terminals, including tin, and having a melting point at a second temperature, wherein the first temperature is lower than the second temperature.

### CROSS-REFERENCE TO RELATED APPLICATION

This application is based on and claims ranking under 35 U.S.C. § 119 to Korean Patent Application No. 10-2024-0158289, filed on Nov. 8, 2024 in the Korean Intellectual Property office, the disclosure of which is incorporated by reference herein in its entirety.

### BACKGROUND

### 1. Field

The disclosure relates to a semiconductor package, a semiconductor package including the package substrate, and a manufacturing method of the semiconductor package, and more particularly, to a package substrate to which connection terminals are attached.

### 2. Brief Description of Background Art

Recently, in response to rapid developments in the electronics industry and user demand, electronic devices are being further miniaturized and multi-functionalized, and have a larger capacity, and accordingly, highly integrated semiconductor chips are required. Accordingly, a semiconductor package is being designed that includes a highly integrated semiconductor chip with an increased number of connection terminals for input/output (I/O) while securing connection reliability.

### SUMMARY

According to some embodiments of the present disclosure, a package substrate including a connection terminal having a low melting point and a semiconductor package including the package substrate may be provided.

According to some embodiments of the present disclosure, a package substrate may be provided and include: a base layer comprising a first surface and a second surface opposite to the first surface; a through via extending from the first surface of the base layer to the second surface of the base layer; a first distribution structure on the first surface of the base layer, and including a first distribution pattern and a first interlayer insulating layer that surrounds the first distribution pattern; first bump pads on and connected to the first distribution pattern of the first distribution structure, the first bump pads spaced apart from the base layer with the first distribution structure between the first bump pads and the base layer; a first passivation layer on the first distribution structure and surrounding the first bump pads, the first passivation layer including openings that respectively overlap with the first bump pads in a vertical direction; first connection terminals in the openings of the first passivation layer and on the first bump pads, the first connection terminals including tin(Sn) and having a melting point at a first temperature; and metal protection layers on surfaces of the first connection terminals, the metal protection layers including Sn and having a melting point at a second temperature, wherein the first temperature is lower than the second temperature.

According to some embodiments of the present disclosure, a package substrate may be provided and include: a base layer including a first surface and a second surface opposite to the first surface; a through via extending from the first surface of the base layer to the second surface of the base layer; a first distribution structure on the first surface of the base layer, and including a first distribution pattern and a first interlayer insulating layer surrounding the first distribution pattern; first bump pads on and connected to the first distribution pattern of the first distribution structure, the first bump pads spaced apart from the base layer with the first distribution structure between the first bump pads and the base layer; a first passivation layer on the first distribution structure and surrounding the first bump pads, the first passivation layer including openings that respectively overlap with the first bump pads in a vertical direction; first connection terminals in the openings of the first passivation layer and on the first bump pads, the first connection terminals including tin(Sn) and having a first hardness; metal compound layers on a surface of each of the first connection terminals; and metal protection layers on surfaces of the first connection terminals and the metal compound layers, and having a second hardness greater than the first hardness, wherein a melting point of the first bump pads is lower than a melting point of the metal protection layers.

According to some embodiments of the present disclosure, a semiconductor package may be provided and include a package substrate including: a base layer including a first surface and a second surface opposite to the first surface; a first distribution structure on the first surface of the base layer; a second distribution structure on the second surface of the base layer; a through via that penetrates the base layer and connects the first distribution structure to the second distribution structure; first bump pads under a lower surface of the first distribution structure; second bump pads on an upper surface of the second distribution structure; and a first passivation layer that surrounds the first bump pads and includes openings that overlap with the first bump pads in a vertical direction. The semiconductor package may further include: a main substrate, wherein the package substrate is on an upper surface of the main substrate, and the main substrate includes substrate bump pads at the upper surface of the main substrate; substrate connection terminals between the package substrate and the main substrate, and configured to electrically, physically, and respectively connect the first bump pads of the package substrate to the substrate bump pads of the main substrate, the substrate connection terminals having a melting point at a first temperature; metal protection fragments inside each of the substrate connection terminals, and having a melting point at a second temperature that is higher than the first temperature; a semiconductor chip on an upper surface of the second distribution structure of the package substrate; chip connection terminals between the package substrate and the semiconductor chip, and configured to electrically, physically, and respectively connect the second bump pads of the package substrate to chip pads of the semiconductor chip; and a molding layer on the package substrate and surrounding the semiconductor chip.

According to some embodiments of the present disclosure, a manufacturing method of a semiconductor package may include: manufacturing a package substrate including a base layer, a first distribution structure arranged on a first surface of the base layer, first bump pads arranged on the first distribution structure, and a second distribution structure arranged on a second surface opposite to the first surface of the base layer; and mounting a semiconductor chip onto the second distribution structure of the package substrate, wherein the manufacturing of the package substrate includes attaching first connection terminals onto the first bump pads, forming a protection layer on the first distribution structure so that at least portions of surfaces of the first connection terminals are exposed, forming, on the first connection terminals, metal protection layers having a higher melting point than the first connection terminals, and removing the protection layer.

In an embodiment of the disclosure, each of the substrate connection terminals comprises about 30 wt % to about 60 wt % of tin, and each of the metal protection fragments comprises about 95 wt % to about 99 wt % of tin.

In an embodiment of the disclosure, each of the substrate connection terminals has a first hardness and a first tensile strength, and each of the metal protection fragments has a second hardness greater than the first hardness and a second tensile strength greater than the first tensile strength.

According to some embodiments of the present disclosure, a manufacturing method of a semiconductor package may include manufacturing a package substrate including a base layer, a first distribution structure arranged on a first surface of the base layer, first bump pads arranged on the first distribution structure, and a second distribution structure arranged on a second surface opposite to the first surface of the base layer, and mounting a semiconductor chip onto the second distribution structure of the package substrate, wherein the manufacturing of the package substrate includes attaching first connection terminals onto the first bump pads, forming a protection layer on the first distribution structure so that at least portions of surfaces of the first connection terminals are exposed, forming, on the first connection terminals, metal protection layers having a higher melting point than the first connection terminals, and removing the protection layer.

In an embodiment of the present disclosure, the manufacturing method further comprising attaching the package substrate onto a main substrate by applying heat to the package substrate, wherein, in the attaching of the package substrate onto the main substrate, the metal protection layers of the package substrate are fused with the first connection terminals to become substrate connection terminals configured to electrically and physically connect the package substrate to the main substrate.

In an embodiment of the present disclosure, in the attaching of the package substrate onto the main substrate, portions of the metal protection layers are not fused with first connection terminals, and remain inside the substrate connection terminals.

In an embodiment of the present disclosure, each of the first connection terminals comprises about 30 wt % to about 60 wt % of tin, and each of the metal protection layers comprises about 95 wt % to about 99 wt % of tin.

In an embodiment of the present disclosure, in the attaching of the first connection terminal, metal compound layers are formed on surfaces of the first connection terminals.

In an embodiment of the present disclosure, in the forming of the metal protection layers, when portions of surfaces of the first connection terminals are in contact with the protection layer, the metal protection layers are not formed at portions where the protection layer is in contact with the first connection terminals.

Aspects of embodiments of the present disclosure and issues solved by embodiments of the present disclosure are not limited to the above-mentioned aspects and issues, and other aspects of embodiments of the present disclosure and issues solved by embodiments of the present disclosure not mentioned may be clearly understood by those of ordinary skill in the art from the following descriptions.

### BRIEF DESCRIPTION OF DRAWINGS

Embodiments will be more clearly understood from the following detailed description taken in conjunction with the accompanying drawings in which:

FIG. 1A is a schematic cross-sectional views of package substrates according to an embodiment;

FIG. 1B is a schematic cross-sectional views of package substrates according to an embodiment;

FIG. 2 is a schematic enlarged view of a portion EX in the package substrate of FIG. 1A;

FIG. 3 is a schematic enlarged cross-sectional view of a portion of a package substrate, according to an embodiment;

FIG. 4 is a schematic enlarged cross-sectional view of a portion of a package substrate, according to an embodiment;

FIG. 5 is a schematic enlarged cross-sectional view of a portion of a package substrate, according to an embodiment;

FIG. 6 is a schematic enlarged cross-sectional view of a portion of a package substrate, according to an embodiment;

FIG. 7 is a schematic enlarged cross-sectional view of a portion of a package substrate, according to an embodiment;

FIG. 8 is a schematic enlarged cross-sectional view of a portion of a package substrate, according to an embodiment;

FIG. 9 is a schematic enlarged cross-sectional view of a portion of a package substrate, according to an embodiment;

FIG. 10 is a cross-sectional view of a semiconductor package according to an embodiment;

FIG. 11 is a schematic flowchart of processes of a manufacturing method of a semiconductor package, according to embodiments;

FIGS. 12A through 12F are cross-sectional views illustrating a manufacturing method of a semiconductor package, according to embodiments;

FIG. 13 is a schematic flowchart of processes of a manufacturing method of a semiconductor package, according to embodiments;

FIGS. 14A through 14B are diagrams illustrating portions of a testing method of a semiconductor package, according to embodiments;

FIG. 15 is a cross-sectional view illustrating a manufacturing method of a semiconductor package, according to an embodiment; and

FIG. 16 is a cross-sectional view of a semiconductor package according to an embodiment.

### DETAILED DESCRIPTION

Non-limiting example embodiments of the present disclosure are described below, and illustrated in the drawings, to more completely explain the present disclosure to those of ordinary skill in the art. The example embodiments may be modified in various different forms, and the scope of the present disclosure is not limited to the example embodiments. Rather, various changes in form and details may be made to embodiments of the present disclosure without departing from the spirit and scope of the present disclosure.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

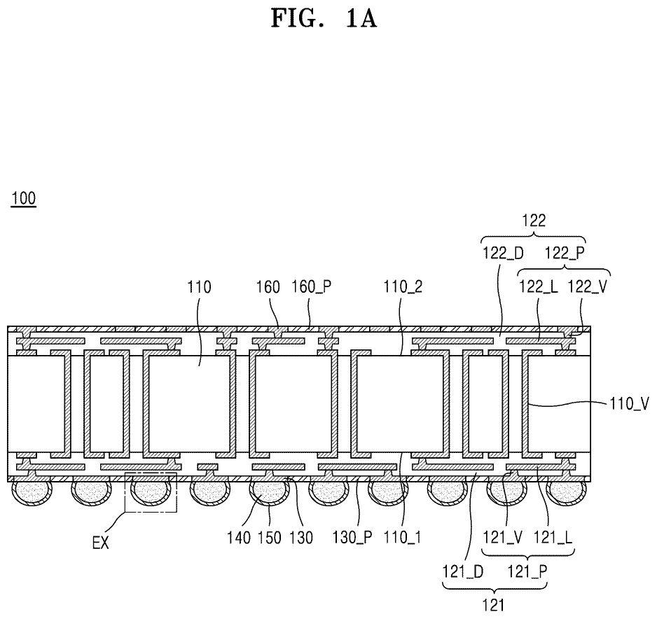

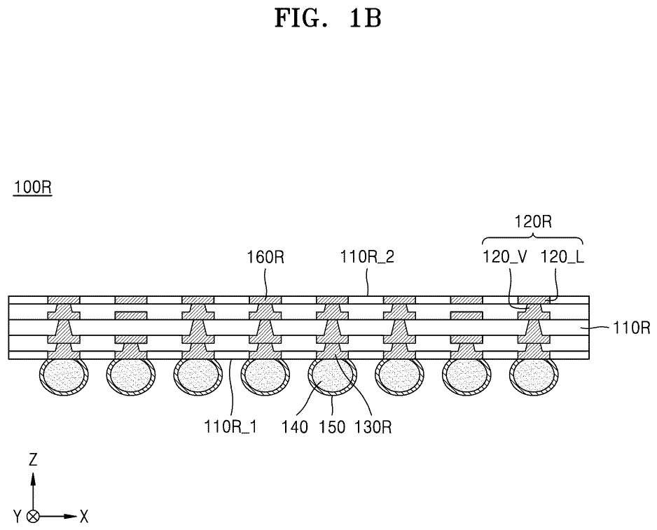

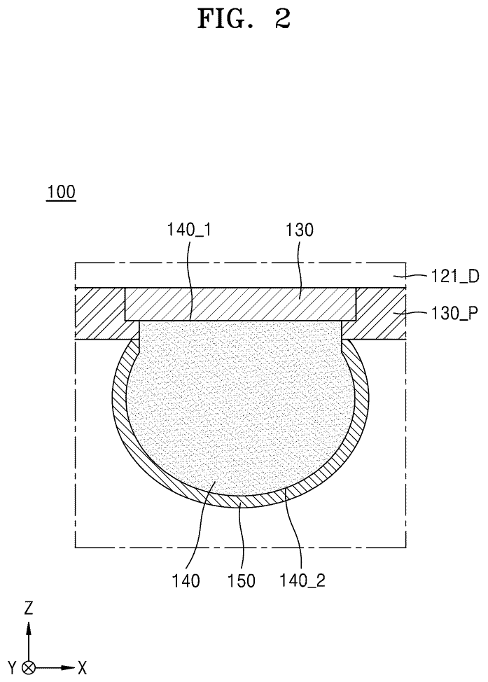

FIGS. 1A and 1B are schematic cross-sectional views of package substrates 100 and 100R according to embodiments, respectively. FIG. 2 is a schematic enlarged view of a portion EX in the package substrate 100 of FIG. 1A.

Referring to FIGS. 1A and 2, the package substrate 100 may include a base layer 110, a through via 110_V, a first distribution structure 121, a second distribution structure 122, first bump pads 130, second bump pads 160, first connection terminals 140, and metal protection layers 150. In some embodiments, the package substrate 100 may include a printed circuit board (PCB) or a module substrate on which a semiconductor chip is mounted.

Hereinafter, unless otherwise defined, a direction in parallel with an upper surface of the base layer 110 may be defined as a first horizontal direction (e.g., X direction), a direction perpendicular to the upper surface of the base layer 110 may be defined as a vertical direction (e.g., Z direction), and a direction perpendicular to the first horizontal direction (e.g., X direction) and the vertical direction (e.g., Z direction) may be defined as a second horizontal direction (e.g., Y direction). A horizontal direction may be defined as including the first horizontal direction (e.g., X direction) and/or the second horizontal direction (e.g., Y direction).

The base layer 110 may include a first surface 110_1 and a second surface 110_2 opposite to each other, and each of the first surface 110_1 and the second surface 110_2 of the base layer 110 may be planar. The base layer 110 may generally have a flat plate shape or a panel shape. For example, referring to FIG. 1, the first surface 110_1 of the base layer 110 may be referred to as a lower surface of the base layer 110, and the second surface 110_2 of the base layer 110 may be referred to as an upper surface of the base layer 110.

The base layer 110 may include at least one material from among a phenol resin, an epoxy resin, and polyimide. For example, the base layer 110 may include at least one material from among prepreg, polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The base layer 110 may further include the through via 110_V. The through via 110_V may penetrate the base layer 110, and may extend from the first surface 110_1 of the base layer 110 to the second surface 110_2 of the base layer 110. The through via 110_V may electrically connect the first distribution structure 121 to the second distribution structure 122. For example, a first portion of the through via 110_V may be in contact with a first distribution pattern 121_P of the first distribution structure 121, and a second portion the through via 110_V may be in contact with a second distribution pattern 122_P of the second distribution structure 122.

For example, the through via 110_V may be conformally formed on a side surface of a through hole after forming the through hole extending from the first surface 110_1 of the base layer 110 to the second surface 110_2 of the base layer 110. For example, the through via 110_V may be formed by using an electroplating process.

The first distribution structure 121 may be arranged on the first surface 110_1 of the base layer 110. The first distribution structure 121 may include multiple distribution layers. For example, the first distribution structure 121 may include four to eight distribution layers. However, the number of layers of the first distribution structure 121 is not limited thereto.

The thickness of the first distribution structure 121 may vary according to the number of distribution layers included in the first distribution structure 121. In some embodiments, the thickness of the first distribution structure 121 may be about 100 μm to about 1000 μm.

Each of the multiple distribution layers of the first distribution structure 121 may include a respective one of first distribution patterns 121_P and a respective one of first interlayer insulating layers 121_D surrounding the first distribution pattern 121_P. The first distribution pattern 121_P may include a first distribution line 121_L extending in the horizontal direction on the first interlayer insulating layer 121_D, and a first distribution via 121_V extending in the vertical direction (e.g., Z direction) from the first distribution line 121_L. In some embodiments, the first interlayer insulating layer 121_D of each of the multiple distribution layers of the first distribution structure 121 may be integrally formed (e.g., form one body) without a boundary surface therein.

For example, the first interlayer insulating layer 121_D may insulate the first distribution lines 121_L arranged in different distribution layers from each other. The first distribution via 121_V may penetrate the first interlayer insulating layer 121_D to be electrically connected to the first distribution lines 121_L arranged in different distribution layers.

The second distribution structure 122 may be formed on the second surface 110_2 of the base layer 110. The second distribution structure 1221 may include multiple distribution layers. For example, the second distribution structure 122 may include four to eight distribution layers. However, the number of layers of the second distribution structure 122 is not limited thereto.

The thickness of the second distribution structure 122 may vary according to the number of distribution layers included in the second distribution structure 122. In some embodiments, the number of distribution layers of the second distribution structure 122 may be the same as or different from the number of distribution layers of the first distribution structure 121. In some embodiments, the thickness of the second distribution structure 122 may be about 100 μm to about 1000 μm.

Each of the multiple distribution layers of the second distribution structure 122 may include a respective one of second distribution patterns 122_P and a respective one of second interlayer insulating layers 122_D surrounding the second distribution pattern 122_P. The second distribution pattern 122_P may include a second distribution line 122_L extending in the horizontal direction on a second interlayer insulating layer 122_D and a second distribution via 122_V extending in the vertical direction (e.g., Z direction) from the second distribution line 122_L. In some embodiments, the second interlayer insulating layer 122_D of each of the multiple distribution layers of the second distribution structure 122 may be integrally formed (e.g., form one body) without a boundary surface therein.

For example, the second interlayer insulating layer 122_D may insulate the second distribution lines 122_L arranged in different distribution layers from each other. The second distribution via 122_V may penetrate the second interlayer insulating layer 122_D to be electrically connected to the second distribution lines 122_L arranged in different distribution layers.

In some embodiments, the first distribution pattern 121_P and the second distribution pattern 122_P may include a metal such as, for example, copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. In some embodiments, the first interlayer insulating layer 121_D and the second interlayer insulating layer 122_D may include poly propylene glycol (PPG). However, the material of the first interlayer insulating layer 121_D and the second interlayer insulating layer 122_D is not limited thereto.

The first bump pads 130 may be arranged on the first distribution structure 121, and electrically connected to the first distribution pattern 121_P of the first distribution structure 121. For example, the first bump pads 130 may be apart from the base layer 110 and may be arranged on the first distribution structure 121. The first bump pads 130 may be arranged on a lower surface of the first distribution structure 121.

The second bump pads 160 may be arranged on the second distribution structure 122, and electrically connected to the second distribution pattern 122_P of the second distribution structure 122. The second bump pads 160 may be apart from the base layer 110 and may be arranged on the second distribution structure 122. The second bump pads 160 may be arranged on an upper surface of the second distribution structure 122.

In some embodiments, the first bump pads 130 may be referred to as lower bump pads, and the second bump pads 160 may be referred to as upper bump pads. In some embodiments, the first bump pads 130 may be a portion of the first distribution pattern 121_P, and the second bump pads 160 may be a portion of the second distribution pattern 122_P. For example, the first bump pads 130 may include a portion of the first distribution line 121_L arranged in a lowermost distribution layer, and the second bump pads 160 may include a portion of the second distribution line 122_L arranged in an uppermost distribution layer.

For example, the first bump pads 130 and the second bump pads 160 may include a conductive material such as, for example, Cu, Al, silver (Ag), Sn, gold (Au), Ni, lead (Pb), Ti, or an alloy thereof.

At least one first passivation layer 130_P may be on the lower surface of the first distribution structure 121, and may surround the first bump pads 130. The first passivation layer 130_P may include openings overlapping with the first bump pads 130 in the vertical direction (e.g., Z direction). Lower surfaces of the first bump pads 130 may be exposed to the outside via the openings of the first passivation layer 130_P.

In some embodiments, a thickness of the first passivation layer 130_P may be greater than a thickness of each of the first bump pads 130. A side surface of the first passivation layer 130_P may be aligned with (e.g., coplanar with) a side surface of the first distribution structure 121 in the vertical direction (e.g., Z direction). In some embodiments, a width of each of the openings of the first passivation layer 130_P may be less than a width of each of the first bump pads 130.

A second passivation layer 160_P may be arranged on the second distribution structure 122, and may surround the second bump pads 160. In some embodiments, the second passivation layer 160_P may include openings overlapping with the second bump pads 160 in the vertical direction (e.g., Z direction). Upper surfaces of the second bump pads 160 may be exposed to the outside via the openings of the second passivation layer 160_P. A side surface of the second passivation layer 160_P may be aligned with (e.g., coplanar with) a side surface of the second distribution structure 122 in the vertical direction (e.g., Z direction). In some embodiments, a width of each of the openings of the first passivation layer 130_P may be less than a width of each of the first bump pads 130.

The first connection terminals 140 may be respectively arranged under the first bump pads 130. For example, each of the first connection terminals 140 may be arranged inside the opening of the first passivation layer 130_P, and may be in contact with a respective one of the first bump pads 130. For example, each of the first connection terminals 140 may be in contact with a sidewall of the first passivation layer 130_P which defines an opening of the first passivation layer 130_P.

Each of the first connection terminals 140 may include a first surface 140_1 and a second surface 140_2. The first surface 140_1 of the first connection terminals 140 may include a portion of the first connection terminals 140 in contact with one of the first bump pads 130 and the first passivation layer 130_P, and the second surface 140_2 of the first connection terminals 140 may include another portion of the first connection terminals 140.

The first connection terminals 140 may be configured to electrically and physically connect the package substrate 100 and an external device on which the package substrate 100 is mounted. For example, the first connection terminals 140 may include solder balls or solder bumps. For example, the first connection terminals 140 may include low melting point solder balls or low melting point solder bumps having a relatively low melting point.

Each of the metal protection layers 150 may be arranged on the second surface 140_2 of a respective one of the first connection terminals 140. For example, each of the metal protection layers 150 may cover the second surface 140_2 of a first connection terminal 140 corresponding to the metal protection layer 150, among the first connection terminals 140. In some embodiments, the first surface 140_1 of the first connection terminals 140 may be in contact with the first bump pads 130 and/or the first passivation layer 130_P, and the second surface 140_2 of the first connection terminals 140 may be in contact with the metal protection layers 150. In some embodiments, the first connection terminals 140 and the metal protection layers 150 may be collectively referred to as bumps.

In some embodiments, the first connection terminals 140 may include solder balls having a diameter of about 100 μm to about 600 μm. For example, a maximum width of each of the first connection terminals 140 may be about 100 μm to about 600 μm. In the present disclosure, the width of each of the first connection terminals 140 may mean a length of each of the first connection terminals 140 in the horizontal direction (e.g., the X direction or the Y direction).

For example, each of the metal protection layers 150 may be conformally formed on the second surface 140_2 of the first connection terminal 140 corresponding to the metal protection layer 150, among the first connection terminals 140. For example, the first connection terminals 140 may be completely covered by the metal protection layers 150, and may not be exposed to the outside.

In some embodiments, each of the metal protection layers 150 may have a thickness of about 3 μm to about 10 μm. In the present disclosure, a surface of the metal protection layers 150 in contact with the first connection terminals 140 may be referred to as an internal surface, a surface of the metal protection layer 150 exposed to the outside may be referred to as an external surface, and a distance from the internal surface of the metal protection layers 150 to the external surface of the metal protection layers 150 may be referred to as a thickness of the metal protection layers 150. In the present disclosure, the metal protection layers 150 being conformally formed may mean that the thickness of each of metal protection layers 150 is uniformly formed.

Each of the first connection terminals 140 and the metal protection layers 150 may include Sn as a constituent material. The melting point of each of the first connection terminals 140 may be a first temperature, and the melting point of each of the metal protection layers 150 may be a second temperature. For example, the first temperature may be lower than the second temperature. Each of the metal protection layers 150 may have a melting point higher than a melting point of the first connection terminals 140. In some embodiments, the first temperature may be about 140 degrees Celsius to about 180 degrees Celsius, and the second temperature may be about 200 degrees Celsius to about 240 degrees Celsius.

In some embodiments, each of the first connection terminals 140 may have a first hardness, and each of the metal protection layers 150 may have a second hardness. The first hardness may be less than the second hardness. For example, because the metal protection layers 150 may have a higher hardness than a hardness of the first connection terminals 140, deformation due to an external force in the metal protection layers 150 may be less than deformation due to an external force in the first connection terminals 140. In some embodiments, at a temperature at which a burn-in test is performed, the first hardness may be about 60% to about 75% of the second hardness.

In some embodiments, each of the first connection terminals 140 may have a first tensile strength, and each of the metal protection layers 150 may have a second tensile strength. The first tensile strength may be less than the second tensile strength. For example, because the metal protection layers 150 may have a higher tensile strength than a tensile strength of the first connection terminals 140, a crumbling phenomenon due to an external force in the metal protection layers 150 may be less than a crumbling phenomenon due to an external force in the first connection terminals 140. In some embodiments, at a temperature at which the burn-in test is performed, the first tensile strength may be about 50% to about 75% of the second tensile strength.

For example, each of the first connection terminals 140 may include a solder alloy including about 30 wt % to about 60 wt % of Sn. Each of the metal protection layers 150 may include a solder alloy including about 96 wt % to about 99 wt % of Sn. For example, the first connection terminals 140 may include tin-bismuth (Sn—Bi)-based solder alloys, and the metal protection layers 150 may include tin-silver-copper (SAC)-based solder alloys.

Because the melting point of the first connection terminals 140 attached to the package substrate 100 may be relatively low, attachment reliability may be improved in the process of mounting the package substrate 100 on an external device. However, in the burn-in test for testing the performance of a package substrate of a comparative embodiment, first connection terminals of the package substrate may be melted, deformed in its appearance, and the burn-in test equipment may be contaminated. In the package substrate 100 according to an embodiment of the present disclosure, because the metal protection layers 150 surrounding the surfaces of the first connection terminals 140 have a higher melting point than a melting point of the first connection terminals 140, even when the first connection terminals 140 are melted, contamination of the burn-in test equipment may be suppressed. In addition, the package substrate 100 according to an embodiment of the present disclosure may suppress phenomena of scratches, cracks, or the like from occurring in the first connection terminals 140 and the metal protection layers 150 by using the metal protection layers 150 having higher tensile strength and higher hardness than the first connection terminals 140.

Referring to FIG. 1B, a package substrate 100R may include a base layer 110R, a distribution structure 120R, first bump pads 130R, second bump pads 160R, the first connection terminals 140, and the metal protection layers 150. In some embodiments, the package substrate 100 may include an interposer substrate or a re-distribution layer (RDL).

The base layer 110R may have a multilayer structure in which the distribution structure 120R is arranged on each layer. For example, the base layer 110R may include an insulating material such as, for example, a photo imageable dielectric (PID) resin. In this case, the base layer 110R may further include an inorganic filler.

The distribution structure 120R may be arranged in the base layer 110R. The distribution structure 120R may include a distribution line 120R_L extending in the horizontal direction from an upper surface or a lower surface of each base layer 110R, and a distribution via 120_V extending in the vertical direction (e.g., Z direction) from the distribution line 120R_L. For example, the distribution via 120R_V may penetrate at least a portion of the base layer 110R, and electrically connect a plurality of distribution lines 120R_L to each other at different vertical levels.

In some embodiments, at least one of the distribution lines 120R_L of the distribution structure 120R may be arranged on a first surface 110R_1 of the base layer 110R, and at least one other of the distribution lines 120R_L of the distribution structure 120R may be arranged at (e.g., in or on) a second surface 110R_2 of the base layer 110R. The distribution structure 120R may be electrically connected to an external device on which the package substrate 100R is mounted, and may be electrically connected to an external device mounted on the package substrate 100R.

The distribution structure 120R may include a conductive material such as, for example, Cu, Al, Ag, Sn, Au, Ni, Pb, Ti, or an alloy thereof.

The first bump pads 130R may be arranged at (e.g., in or on) the first surface 110R_1 of the base layer 110R, and the second bump pads 160R may be arranged at (e.g., in or on) the second surface 110R_2 of the base layer 110R. The first bump pads 130R and the second bump pads 160R may be electrically connected to the distribution structure 120R. In some embodiments, the first bump pads 130R may be referred to as lower bump pads, and the second bump pads 160R may be referred to as upper bump pads.

The first connection terminals 140 may be respectively arranged under the first bump pads 130R. The metal protection layer 150 may be on the surface of the first connection terminal 140. For example, the first connection terminals 140 and the metal protection layers 150 may be substantially the same as the first connection terminals 140 and the metal protection layers 150 described with reference to FIG. 1A, respectively.

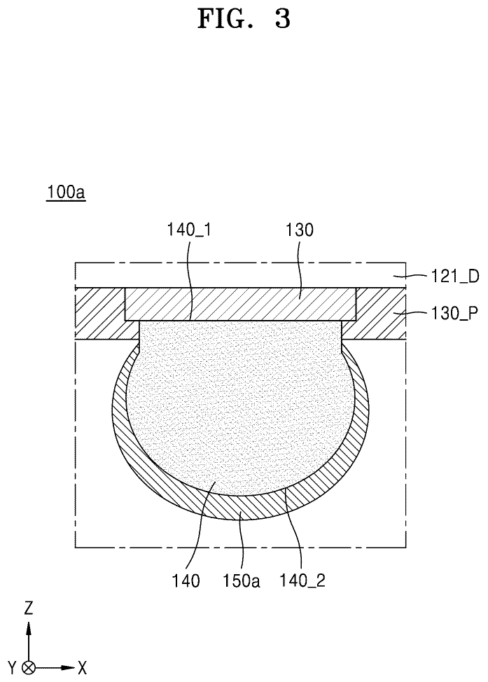

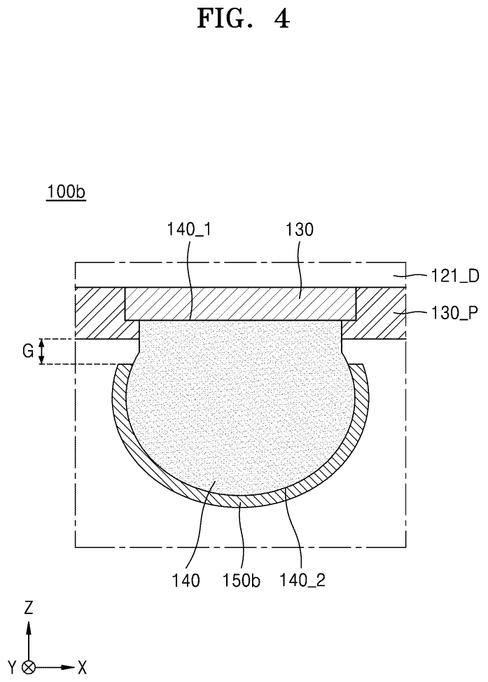

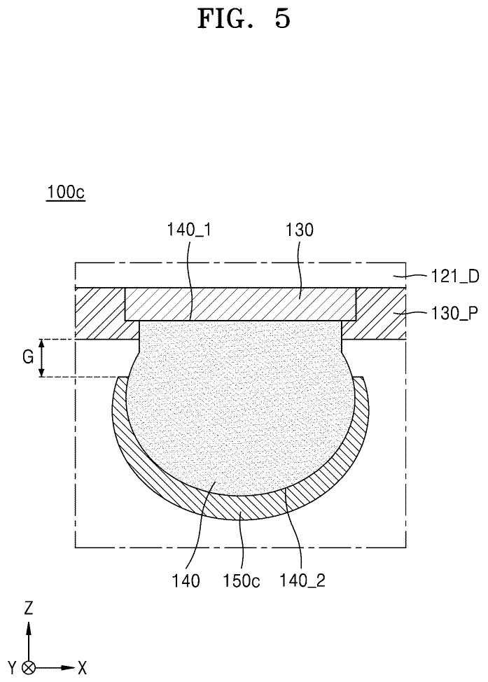

FIG. 3 is a schematic enlarged cross-sectional view of a portion of a package substrate 100a, according to an embodiment. FIG. 4 is a schematic enlarged cross-sectional view of a portion of a package substrate 100b, according to an embodiment. FIG. 5 is a schematic enlarged cross-sectional view of a portion of a package substrate 100c, according to an embodiment.

Most of the components constituting the package substrates 100a, 100b, and 100c and the material constituting the components to be described below may be substantially the same as or similar to those described with reference to FIG. 2. Accordingly, for convenience of description, differences between the package substrates 100a, 100b, and 100c of FIGS. 3, 4, and 5, respectively, and the package substrate 100 of FIG. 2 described above are mainly described.

Referring to FIG. 3 together with FIG. 1, the package substrate 100a may include the base layer 110, the through via 110_V, the first distribution structure 121, the second distribution structure 122, the first bump pads 130, the second bump pads 160, the first connection terminals 140, and metal protection layers 150a.

The first connection terminals 140 may be attached to the first bump pads 130 arranged under the lower surface of the first distribution structure 121. The first connection terminals 140 may be respectively attached onto respective ones of the first bump pads 130. The first connection terminals 140 may include low melting point solder balls or low melting point solder bumps.

Each of the metal protection layers 150a may be arranged on the second surface 140_2 of a respective one of the first connection terminals 140. For example, each of the metal protection layers 150a may cover the second surface 140_2 of the first connection terminal 140 corresponding to the metal protection layer 150a, among the first connection terminals 140. The first connection terminals 140 may be completely covered by the metal protection layers 150a, and may not be exposed to the outside.

The melting point of the metal protection layers 150a may be higher than the melting point of the first connection terminals 140. The tensile strength and hardness of the metal protection layers 150a may be greater than those of the first connection terminals 140. A weight ratio of Sn included in each of the metal protection layers 150a may be greater than a weight ratio of Sn included in each of the first connection terminals 140.

For example, the thickness of the metal protection layers 150a may become greater away from the first passivation layer 130_P. For example, the thickness of the metal protection layers 150a may not be constant.

For example, each of the metal protection layers 150a may have a relatively greater thickness at a lower portion of the first connection terminals 140 than a thickness of a portion of the metal protection layers 150a at a side portion of each of the first connection terminals 140, and thus the degree of deformation of the metal protection layers 150a due to an external force applied at the lower portions of the first connection terminals 140 may be relatively small.

Referring to FIG. 4 together with FIG. 1, the package substrate 100b may include the base layer 110, the through via 110_V, the first distribution structure 121, the second distribution structure 122, the first bump pads 130, the second bump pads 160, the first connection terminals 140, and metal protection layers 150b.

The metal protection layers 150b may be arranged on the surfaces of the first connection terminals 140 respectively attached to the first bump pads 130. The metal protection layers 150b and the first passivation layer 130_P may be apart from each other in the vertical direction (e.g., Z direction), such that a gap G may be formed between each of the metal protection layers 150b and each of the first passivation layer 130_P. The gap G may have a ring shape surrounding the first connection terminals 140. In some embodiments, a length of the gap G in the vertical direction (e.g., Z direction) may be about 10 μm to about 70 μm.

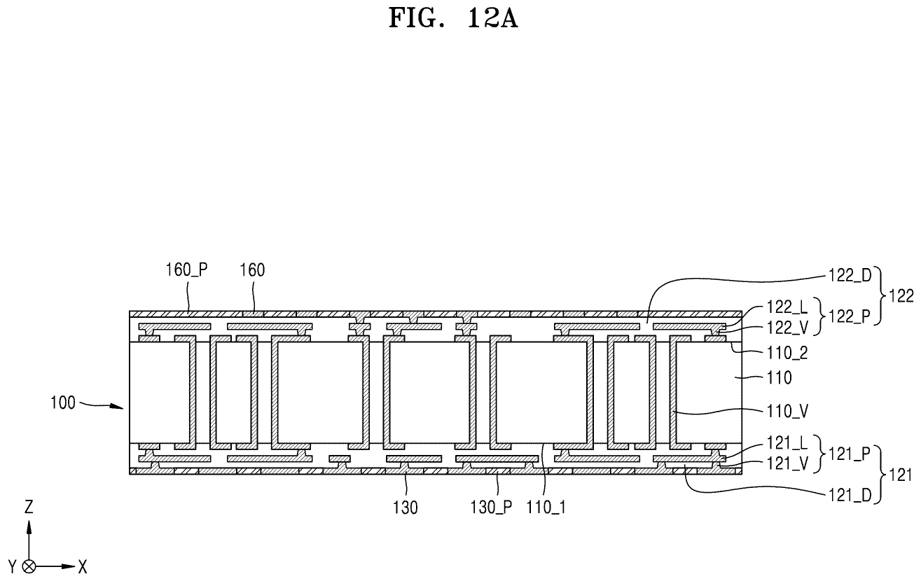

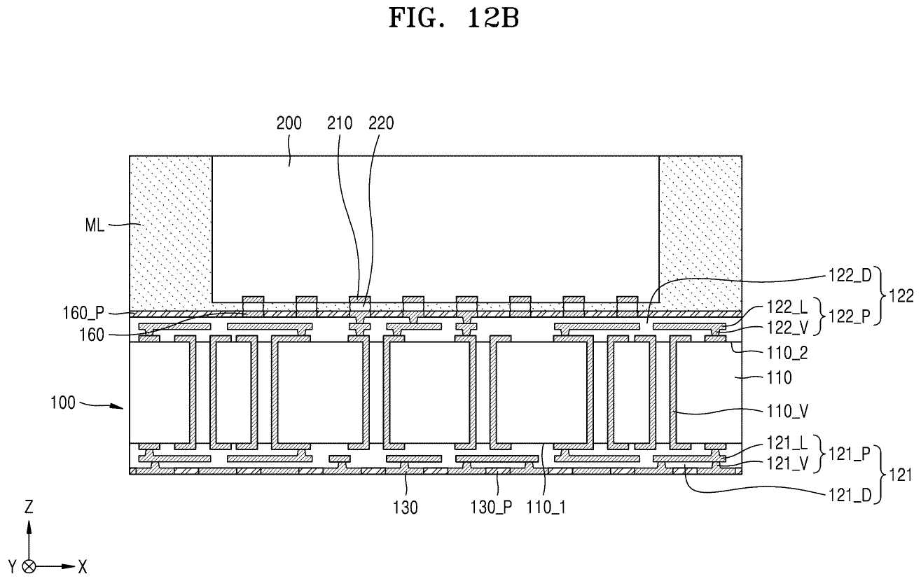

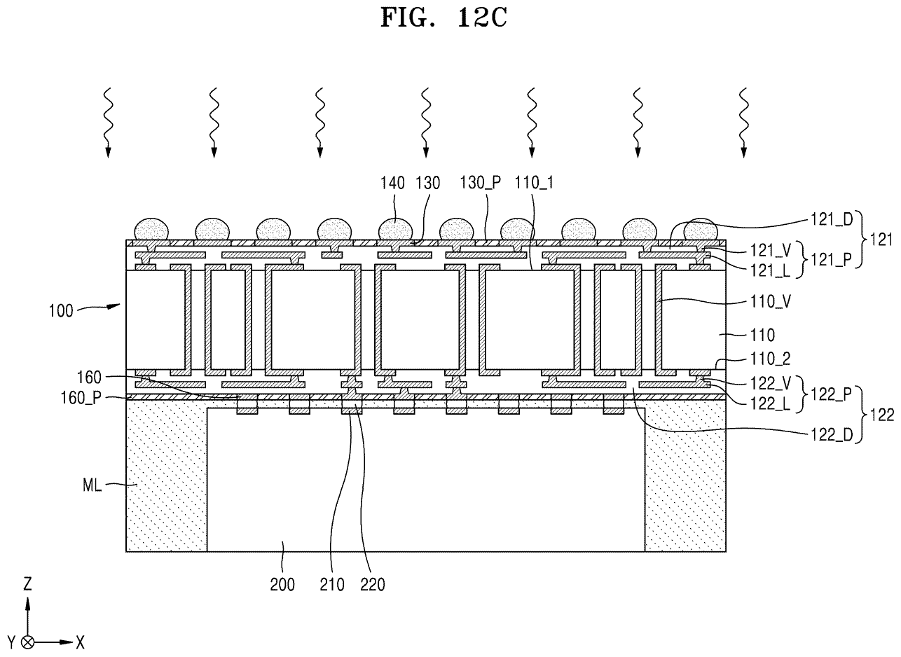

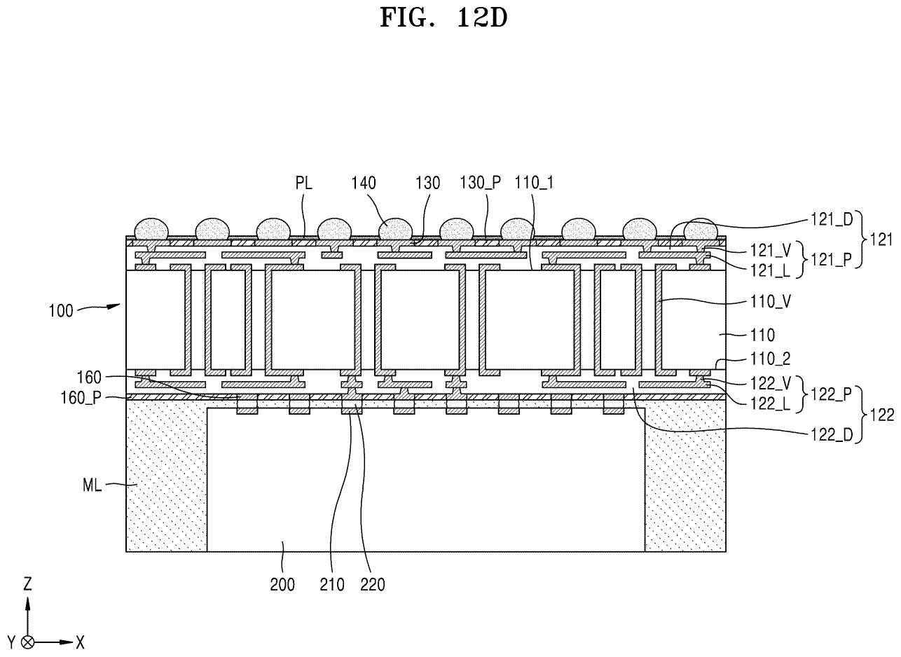

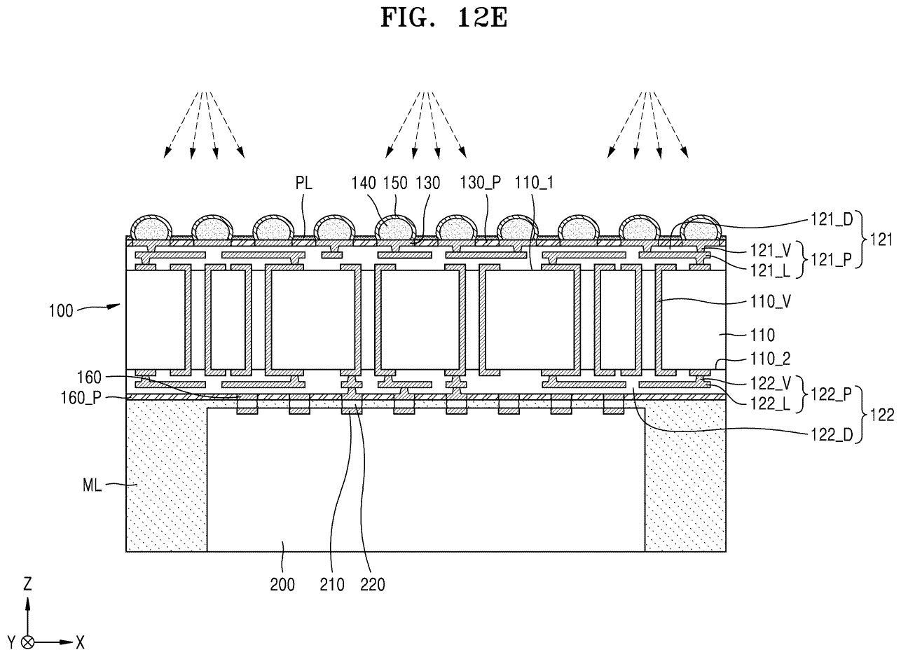

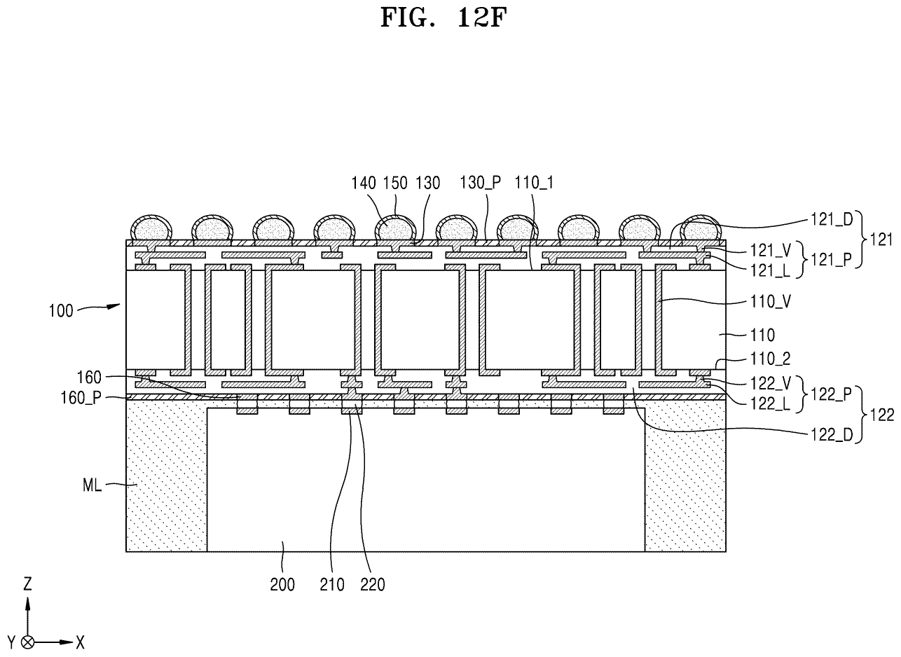

For example, a portion of each of the first connection terminals 140 may be exposed to the outside via the gap G. For example, the gap G may be arranged at a portion of the second surface 140_2 of each of the first connection terminals 140, and thus a portion of the second surface 140_2 may be exposed to the outside. For example, the gap G may be arranged at a portion of the second surfaces 140_2 of the first connection terminals 140, and the metal protection layers 150b may be formed on a remaining portion of the second surfaces 140_2. For example, in the process of forming the metal protection layers 150b, a portion of the second surfaces 140_2 of the first connection terminals 140 may be covered by a protection layer (e.g., protection layer PL in FIG. 12D), and the gap G in which the metal protection layers 150b are not formed may be formed.

The metal protection layers 150b may be conformally formed on the second surface 140_2 of the first connection terminals 140. For example, each of the metal protection layers 150b may have a constant thickness. In some embodiments, each of the metal protection layers 150 b may have a thickness of about 3 μm to about 10 μm.

Referring to FIG. 5 together with FIG. 1, the package substrate 100c may include the base layer 110, the through via 110_V, the first distribution structure 121, the second distribution structure 122, the first bump pads 130, the second bump pads 160, the first connection terminals 140, and metal protection layers 150c.

The metal protection layers 150c may be arranged on the surfaces of the first connection terminals 140 respectively attached to the first bump pads 130. The metal protection layers 150c may be apart from the first bump pads 130 in the vertical direction (e.g., Z direction), such that the gap G may be formed. For example, a portion of a surface of the first connection terminal 140 may be exposed to the outside via the gap G. For example, the gap G may have a ring shape having a constant length in the vertical direction (e.g., Z direction).

The thickness of the metal protection layers 150c may be greater away from the first passivation layer 130_P. For example, the thickness of the metal protection layers 150c formed on the first connection terminals 140 may not be constant. For example, each of the metal protection layers 150c may have a relatively greater thickness at a portion of the metal protection layers 150c arranged under a lower portion of each of the first connection terminals 140 than at portions of the metal protection layers 150c arranged on side portions of each of the first connection terminals 140.

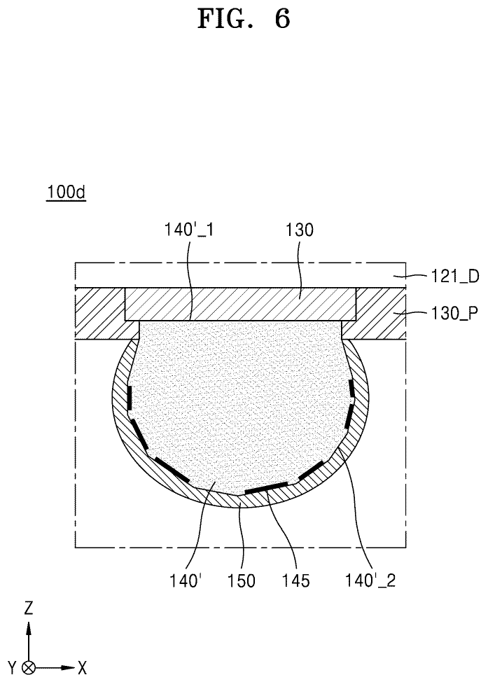

FIG. 6 is a schematic enlarged cross-sectional view of a portion of a package substrate 100d, according to an embodiment.

Most of components constituting the package substrate 100d and materials constituting the components to be described below may be substantially the same as or similar to those described above with reference to FIG. 2. Accordingly, for convenience of explanation, the difference between the package substrate 100d of FIG. 6 and the package substrate 100 of FIG. 2 described above is mainly described.

Referring to FIG. 6 together with FIG. 1, the package substrate 100d may include the base layer 110, the through via 110_V, the first distribution structure 121, the second distribution structure 122, the first bump pads 130, the second bump pads 160, first connection terminals 140′, metal compound layers 145, and the metal protection layers 150.

The first bump pads 130 may be electrically connected to the first distribution structure 121, and may be formed under the lower surface of the first distribution structure 121. Each of the first connection terminals 140′ may be arranged inside the opening of the first passivation layer 130_P, and may be in contact with a respective one of the first bump pads 130.

Each of the first connection terminals 140′ may include a first surface 140′_1 and a second surface 140′_2. For example, the first surface 140′_1 of the first connection terminals 140′ may include a portion in contact with one of the first bump pads 130 and the first passivation layer 130_P, and the second surface 140′_2 of the first connection terminals 140′ may include another portion not in contact with the first bump pads 130.

Each of the metal compound layers 145 may be arranged on the second surface 140′_2 of a respective one of the first connection terminals 140′. For example, each of the metal compound layers 145 may be arranged on the second surface 140′_2 of a respective one of the first connection terminals 140′. For example, an area of each of the metal compound layers 145 may be less than an area of the second surface 140′_2 of each of the first connection terminals 140′, and accordingly, each of the metal compound layers 145 may not completely cover the second surface 140′_2 of the first connection terminals 140′.

In some embodiments, the metal compound layers 145 may be formed on the second surface 140′_2 of the first connection terminals 140′ by using a chemical reaction between the first connection terminals 140′ and the first bump pads 130, in a process of attaching the first connection terminals 140′ to the first bump pads 130. For example, the metal compound layers 145 may include Au as a constituent material.

The metal protection layers 150 may be arranged on the second surface 140′_2 and the metal compound layers 145 of the first connection terminals 140′. For example, the metal protection layers 150 may surround the first connection terminals 140′ and the metal compound layers 145. The metal compound layers 145 may be arranged between the metal protection layers 150 and the first connection terminals 140′. For example, the metal compound layers 145 may be completely covered by the metal protection layers 150, and may not be exposed to the outside.

For example, each of the metal protection layers 150 may be conformally formed on the second surface 140′_2 of a first connection terminal 140′ corresponding to the metal protection layer 150, among the first connection terminals 140′. In some embodiments, each of the metal protection layers 150 may have a thickness of about 3 μm to about 10 μm.

In some embodiments, the first connection terminals 140′ may include low melting point solder balls or low melting point solder bumps. A portion of the surface of each of the first connection terminals 140′ may be edged. For example, portions of the second surface 140′_2 of each of the first connection terminals 140′ may be edged. For example, the first connection terminals 140′ may have a spherical shape in which a portion thereof is cut. For example, in the process of attaching the first connection terminals 140′ to the first bump pads 130, portions of the second surface 140′_2 of the first connection terminals 140′ may be edged by using a chemical reaction between the first connection terminals 140′ and the first bump pads 130.

The melting point of the metal protection layers 150 may be higher than the melting point of the first connection terminals 140′. The tensile strength and hardness of the metal protection layers 150 may be greater than those of the first connection terminals 140′. A weight ratio of Sn included in each of the metal protection layers 150 may be greater than a weight ratio of Sn included in each of the first connection terminals 140′.

For example, a melting point of each of the first connection terminals 140′ may be about 140° C. to about 180° C., and a melting point of each of the metal protection layers 150 may be about 200° C. to about 240° C. At a temperature at which the burn-in test is performed, the hardness of each of the first connection terminals 140′ may be about 60% to about 75% of the hardness of each of the metal protection layers 150. At a temperature at which the burn-in test is performed, the tensile strength of each of the first connection terminals 140′ may be about 50 % to about 75 % of the tensile strength of each of the metal protection layers 150. Each of the first connection terminals 140′ may include a solder alloy including about 30 wt % to about 60 wt % of Sn. Each of the metal protection layers 150 may include a solder alloy including about 96 wt % to about 99 wt % of Sn.

The metal compound layers 145 may have a first reflectance, and the metal protection layers 150 may have a second reflectance. For example, the first reflectance may be greater than the second reflectance. In addition, the metal compound layers 145 may have a higher reflectance than the reflectance of the metal protection layers 150 and the first connection terminals 140. In other words, when the same light is incident on each of the metal compound layers 145 (e.g., metal compound films) and the metal protection layers 150, the metal compound layers 145 may reflect a greater amount of light than the metal

### Protection Layers 150.

In the process of performing the appearance test to determine whether bumps are attached to the package substrate 100d, when the metal compound layers 145 are exposed to the outside, the metal compound layers 145 may reflect a large amount of light, and accordingly, the reliability of the appearance test may be reduced in a comparative embodiment. The metal compound layers 145 may be covered by the metal protection layers 150, and may not be exposed to the outside. Thus, in the package substrate 100d of an embodiment of the present disclosure, the metal compound layers 145 may be covered with the metal protection layers 150, the amount of light reflected during the test may be reduced, and the reliability of the appearance test may be improved.

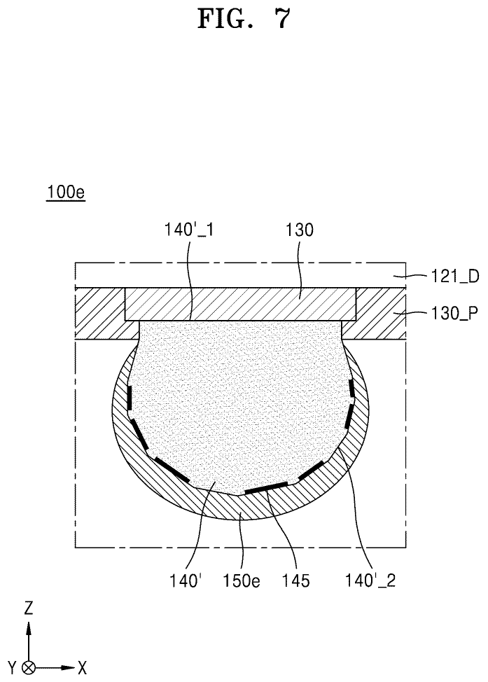

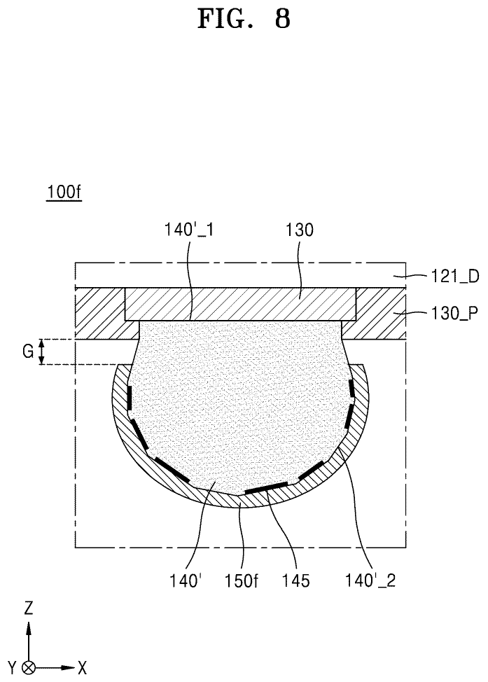

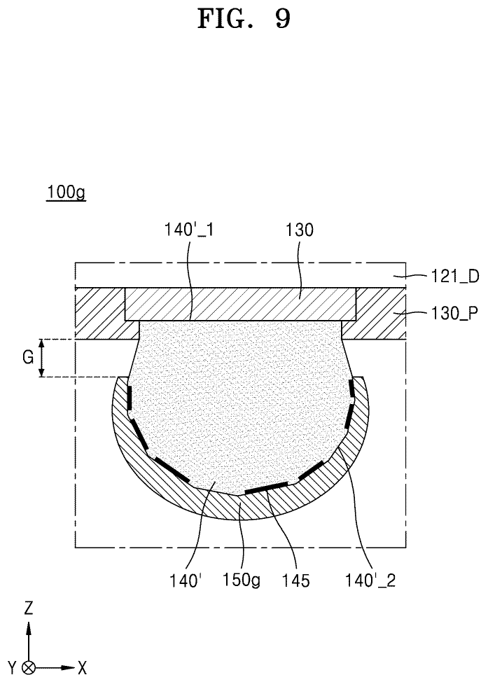

FIG. 7 is a schematic enlarged cross-sectional view of a portion of a package substrate 100e, according to an embodiment. FIG. 8 is a schematic enlarged cross-sectional view of a portion of a package substrate 100f, according to an embodiment. FIG. 9 is a schematic enlarged cross-sectional view of a portion of a package substrate 100g, according to an embodiment.

Most of the components constituting the package substrates 100e, 100f, and 100g and the material constituting the components to be described below may be substantially the same as or similar to those described with reference to FIG. 6. Accordingly, for convenience of description, differences between the package substrates 100e, 100f, and 100g of FIGS. 7, 8, and 9, respectively, and the package substrate 100 d of FIG. 6 described above are mainly described.

Referring to FIG. 7 together with FIG. 1, the package substrate 100e may include the base layer 110, the through via 110_V, the first distribution structure 121, the second distribution structure 122, the first bump pads 130, the second bump pads 160, first connection terminals 140′, metal compound layers 145, and metal protection layers 150e.

The first connection terminals 140′ may be attached to the first bump pads 130 arranged on the lower surface of the first distribution structure 121, and may be arranged inside the opening of the first passivation layer 130_P. The first connection terminals 140′ may include low melting point solder balls or low melting point solder bumps.

Each of the metal protection layers 150e may be arranged on the second surface 140′_2 of the first connection terminals 140′ and the metal compound layers 145. The second surface 140′_2 and the metal compound layers 145 of the first connection terminals 140′ may be covered by metal protection layers 150e, and may not be exposed to the outside.

The metal protection layers 150e may become thicker away from the first passivation layer 130_P. For example, the thickness of the metal protection layers 150e may not be constant.

For example, each of the metal protection layers 150e may have a relatively greater thickness at a lower portion of the first connection terminals 140′ than a thickness at a portion of the metal protection layers 150e at a side portion of each of the first connection terminals 140′, and thus the degree of deformation of the metal protection layers 150e due to an external force applied at the lower portions of the first connection terminals 140′ may be relatively small.

Referring to FIG. 8 together with FIG. 1, the package substrate 100f may include the base layer 110, the through via 110_V, the first distribution structure 121, the second distribution structure 122, the first bump pads 130, the second bump pads 160, first connection terminals 140′, the metal compound layers 145, and metal protection layers 150f.

The metal protection layers 150f may be arranged on the second surface 140′_2 and the metal compound layers 145 of the first connection terminals 140′. The metal protection layers 150f and the first passivation layer 130_P may be apart from each other in the vertical direction (e.g., Z direction), such that the gap G may be formed between each of the metal protection layers 150f and each of the first bump pads 130. The gap G may have a ring shape surrounding the first connection terminals 140′. In some embodiments, ae length of the gap G in the vertical direction (e.g., Z direction) may be about 10 μm to about 70 μm.

For example, a portion of each of the first connection terminals 140′ may be exposed to the outside via the gap G. For example, the gap G may be arranged at a portion of the second surface 140′_2 of each of the first connection terminals 140′, and thus a portion of the second surface 140′_2 may be exposed to the outside. In some embodiments, a portion of the metal compound layers 145 may be arranged in the gap G such as to be exposed to the outside.

The metal protection layers 150f may be conformally formed on the second surface 140′_2 of the first connection terminals 140′. For example, each of the metal protection layers 150f may have a constant thickness. In some embodiments, each of the metal protection layers 150 f may have a thickness of about 3 μm to about 10 μm.

Referring to FIG. 9 together with FIG. 1, the package substrate 100g may include the base layer 110, the through via 110_V, the first distribution structure 121, the second distribution structure 122, the first bump pads 130, the second bump pads 160, first connection terminals 140′, the metal compound layers 145, and metal protection layers 150g.

The metal protection layers 150g may be arranged on the second surface 140′_2 of the first connection terminals 140′ respectively attached to the first bump pads 130. The metal protection layers 150g may be apart from the first bump pads 130 in the vertical direction (e.g., Z direction), and the gap G may be formed. For example, a portion of a surface of the first connection terminal 140′ may be exposed to the outside via the gap G. For example, the gap G may have a ring shape having a constant length in the vertical direction (e.g., Z direction).

The thickness of the metal protection layers 150g may be greater away from the first passivation layer 130_P. For example, the thickness of the metal protection layers 150g formed on the first connection terminals 140′ may not be constant. For example, each of the metal protection layers 150g may have a relatively greater thickness at a portion of the metal protection layers 150g arranged under a lower portion of each of the first connection terminals 140′ than at portions of the metal protection layers 150g arranged on side portions of each of the first connection terminals 140′.

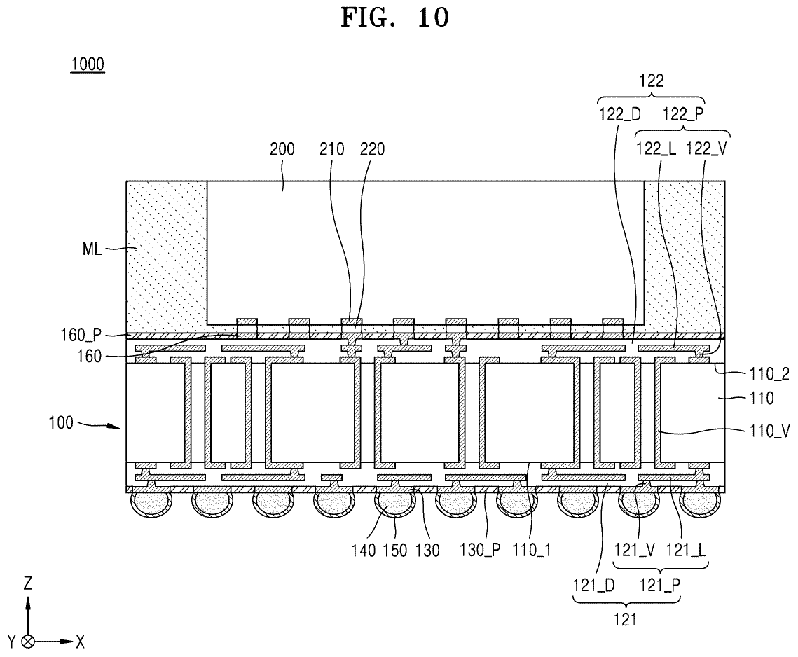

FIG. 10 is a cross-sectional view of a semiconductor package 1000 according to an embodiment.

Referring to FIG. 10, the semiconductor package 1000 may include the package substrate 100, that includes the first connection terminals 140 and the metal protection layers 150, a semiconductor chip 200, and a molding layer ML.

The package substrate 100 may include a base layer 110 including the first surface 110_1 and the second surface 110_2 opposite thereto, the first distribution structure 121 on the first surface 110_1 of the base layer 110, the second distribution structure 122 on the second surface 110_2 of the base layer 110, the through via 110_V electrically connected to the first distribution structure 121 and the second distribution structure 122, the first bump pads 130 on the lower surface of the first distribution structure 121, and the second bump pads 160 on an upper surface of the second distribution structure 122.

The first connection terminals 140 may be attached to the first bump pads 130 of the package substrate 100, and the metal protection layers 150 may be on the surfaces of the first connection terminals 140. The melting point of the first connection terminals 140 may be lower than a melting point of the metal protection layers 150. The hardness of the first connection terminals 140 may be lower than the hardness of the metal protection layers 150. The tensile strength of the first connection terminals 140 may be less than the tensile strength of the metal protection layers 150.

The package substrate 100 may include one of the package substrates 100, 100R, 100a, 100b, 100c, 100d, 100e, 100f, and 100g of FIGS. 1A, 1B, and 2 to 9 described above.

The semiconductor chip 200 may be on the second distribution structure 122 of the package substrate 100. The semiconductor chip 200 may include an active surface and an inactive surface opposite thereto. The semiconductor chip 200 may be arranged on the second surface 110_2 of the base layer 110 of the package substrate 100 so that the active surface faces the package substrate 100. For example, the semiconductor chip 200 may be arranged on the package substrate 100 in a face down manner.

The semiconductor chip 200 may include, for example, a semiconductor material, such as silicon (Si) and germanium (Ge). Alternatively, the semiconductor chip 200 may include a compound semiconductor material, such as silicon carbide (SiC), gallium arsenide (GaAs), indium arsenide (InAs), and indium phosphate (InP). The semiconductor chip 200 may include a well, doped with impurities, which is a conductive region. The semiconductor chip 200 may have various device isolation structures such as a shallow trench isolation (STI) structure.

A semiconductor device including a plurality of individual devices of various types may be formed on the active surface of the semiconductor chip 200. The plurality of individual devices may be included in the conductive region of the semiconductor chip 200.

The semiconductor device may further include a conductive distribution or a conductive plug electrically connecting the plurality of individual devices to the conductive region of the semiconductor chip 200. In addition, each of the plurality of individual devices may be electrically isolated from another adjacent individual device by an insulating layer.

In some embodiments, the semiconductor chip 200 may include a logic device. For example, the semiconductor chip 200 may include a central processing unit chip, a graphics processing unit chip, or an application processor (AP). In some other embodiments, when the semiconductor package 1000 includes a plurality of semiconductor chips 200, one of the plurality of semiconductor chips 200 may include a central processing unit chip, a graphics processing unit chip, or an AP chip, and the other of the plurality of semiconductor chips 200 may include a memory semiconductor chip including a memory device.

For example, the memory device may include, for example, a non-volatile memory device, such as a flash memory, phase change random access memory (RAM) (PRAM), magnetic RAM (MRAM), ferroelectric RAM (FeRAM), and resistive RAM (RRAM). In some embodiments, the memory device may include a volatile memory device, such as dynamic RAM (DRAM) and static RAM (SRAM).

In some embodiments, the semiconductor chip 200 may further include chip pads 210. The chip pads 210 may be electrically connected to the conductive region to the plurality of individual devices via a distribution pattern of the semiconductor chip 200. For example, the chip pads 210 may include a conductive material such as, for example, Al.

Chip connection terminals 220 may be arranged between the semiconductor chip 200 and the package substrate 100. Each of the chip connection terminals 220 may be arranged between the second bump pads 160 of the package substrate 100 and the chip pads 210 of the semiconductor chip 200. The semiconductor chip 200 may be physically and electrically connected to the package substrate 100 via chip connection terminals 220. However, the embodiment is not limited thereto, and the semiconductor chip 200 may be physically and electrically connected to the package substrate 100 by using a hybrid bonding, a direct bonding, a conductive adhesive film, etc.

The molding layer ML may be arranged on the package substrate 100, and may surround the semiconductor chip 200. Side surfaces of the molding layer ML may be aligned with (e.g., coplanar with) side surfaces of the base layer 110 of the package substrate 100 in the vertical direction (e.g., Z direction). An upper surface of the molding layer ML may be coplanar with an upper surface of the semiconductor chip 200. For example, the upper surface of the semiconductor chip 200 may be exposed to the outside.

In some embodiments, the molding layer ML may include an epoxy resin, a polyimide resin, or the like. The molding layer ML may include, for example, an epoxy molding compound (EMC).

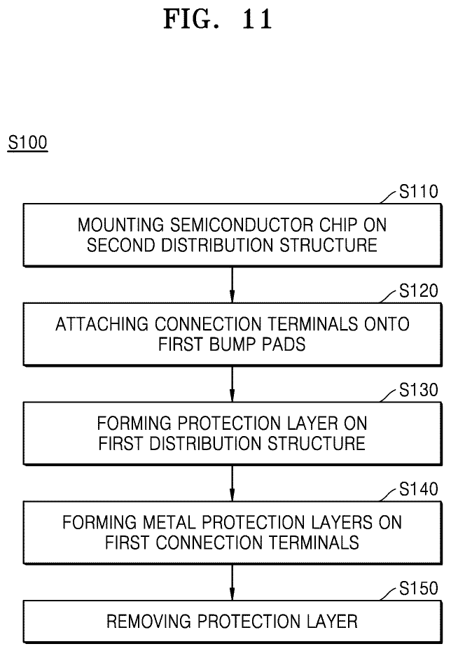

FIG. 11 is a schematic flowchart of processes of a manufacturing method S100 of a semiconductor package, according to embodiments. FIGS. 12A through 12F are cross-sectional views illustrating a manufacturing method of a semiconductor package in sequence, according to embodiments.

Referring to FIG. 11, the manufacturing method S100 of a semiconductor package may include an operation S110 of mounting the semiconductor chip 200 on the second distribution structure 122 of the package substrate 100, an operation S120 of attaching the first connection terminals 140 to the first bump pads 130 of the package substrate 100, an operation S130 of forming a protection layer PL on the first distribution structure 131 of the package substrate 100, an operation S140 of forming the metal protection layers 150 on the first connection terminals 140, and an operation S150 of removing the protection layer PL.

Referring to FIG. 12A, the package substrate 100 may be prepared.

The package substrate 100 may include the base layer 110, the first distribution structure 121 on the first surface 110_1 of the base layer 110, the second distribution structure 122 on the second surface 110_2 of the base layer 110, the through via 110_V penetrating the base layer to electrically connect the first distribution structure 121 to the second distribution structure 122, the first bump pads 130 under the lower surface of the first distribution structure 121, the second bump pads 160 on the upper surface of the second distribution structure 122, the first passivation layer 130_P which surrounds the first bump pads 130 while being arranged under the lower surface of the first distribution structure 121 and includes openings overlapping with the first bump pads 130 in the vertical direction (e.g., Z direction), and the second passivation layer 160_P arranged on the upper surface of the second distribution structure 122 and surrounding the second bump pads 160.

The base layer 110 may include the first surface 110_1 and the second surface 110_2 opposite to the first surface 110_1. According to a direction in which the base layer 110 is arranged, the first surface 110_1 of the base layer 110 may be referred to as a lower surface of the base layer 110, and the second surface 110_2 of the base layer 110 may be referred to as an upper surface of the base layer 110.

FIG. 12B illustrates operation S110 of mounting the semiconductor chip 200 on the upper surface of the second distribution structure 122 in FIG. 11. Referring to FIG. 12B, the semiconductor chip 200 may be mounted on the package substrate 100 so that the chip pads 210 of the semiconductor chip 200 correspond to the second bump pads 160 of the package substrate 100.

The chip pads 210 of the semiconductor chip 200 may be physically and electrically connected to the second bump pads 160 via the chip connection terminals 220. The semiconductor chip 200 may be mounted on the base layer 110 in a face-down manner so that the active surface of the semiconductor chip 200 faces the base layer 110.

Thereafter, the molding layer ML may be formed on the second surface 110_2 of the base layer 110 to surround (e.g., cover) the semiconductor chip 200. The upper portion of the molding layer ML may be removed until the upper surface of the semiconductor chip 200 is exposed.

In an embodiment of the present disclosure, before the first connection terminals 140 and the metal protection layers 150 are formed on the first bump pads 130, the semiconductor chip 200 may be mounted on the second distribution structure 122, but is not limited thereto, and after the first connection terminals 140 and the metal protection layers 150 are formed on the first bump pads 130, the semiconductor chip 200 may be mounted on the second distribution structure 122.

FIG. 12C illustrates the operation S120 of attaching the first connection terminals 140 to the base layer 110 in FIG. 11. Referring to FIG. 12C, the first connection terminals 140 may be attached to the first bump pads 130.

The first connection terminals 140 may include solder balls or solder bumps having relatively low melting points. For example, the melting point of the first connection terminals 140 may be about 140 degrees Celsius to about 180 degrees Celsius. For example, the first connection terminals 140 may include a solder alloy including about 30 wt % to about 60 wt % of Sn. For example, the first connection terminals 140 may include a tin-bismuth (Sn—Bi)-based solder alloy.

For example, after the first connection terminals 140 are respectively mounted on the first bump pads 130, by using a reflow process, the first connection terminals 140 may be attached to the first bump pads 130.

In some embodiments, when the first bump pads 130 include Au, in the process of respectively attaching the first connection terminals 140 to the first bump pads 130 by using a reflow process, the first connection terminals 140 may chemically react with the first bump pads 130. For example, the first connection terminals 140 may chemically react with the first bump pads 130, and metal compound layers (e.g., metal compound layers 145 in FIG. 6) may be formed on the surfaces of the first connection terminals 140. For example, the first connection terminals 140 may chemically react with the first bump pads 130, and a portion of the second surface (e.g., the second surface 140′_2 in FIG. 6) of each of the first connection terminals 140 may be edged.

FIG. 12D illustrates the operation S130 of forming the protection layer PL on the first passivation layer 130_P in FIG. 11. Referring to FIG. 12D, the protection layer PL may be formed on an upper surface of the first passivation layer 130_P.

The protection layer PL may cover the upper surface of the first passivation layer 130_P and portions of side surfaces of the first connection terminals 140. The protection layer PL may include an ultraviolet (UV) ray tape. For example, the protection layer PL may have a thickness of about 30 μm to about 150 μm.

FIG. 12E illustrates the operation S140 of respectively forming metal protection layers 150 on the first connection terminals 140 in FIG. 11. Referring to FIG. 12E, the metal protection layers 150 may be formed on the second surface (e.g., the second surface 140_2 in FIG. 2) of the first connection terminals 140.

The metal protection layers 150 may be formed on a surface of each of the first connection terminals 140, that is exposed to the outside. The metal protection layers 150 may be formed on the surface of each of the first connection terminals 140 so that the thickness of the metal protection layers 150 is about 3 μm to about 10 μm.

In some embodiments, when the protection layer PL is in contact with the first connection terminals 140, the metal protection layers 150 may not be formed on a portion of surfaces of the first connection terminals 140, that is in contact with the protection layer PL. For example, when the protection layer PL is in contact with portions of the side surfaces of the first connection terminals 140, the metal protection layers 150 may be apart from the upper surface of the first passivation layer 130_P in the vertical direction (e.g., Z direction). For example, when the protection layer PL is in contact with the side surfaces of the first connection terminals 140, a protection layer may be arranged between the metal protection layers 150 and the first passivation layer 130_P.

The melting point of the metal protection layers 150 may be higher than the melting point of the first connection terminals 140. The melting point of the metal protection layers 150 may be about 200 degrees Celsius to about 240 degrees Celsius. The metal protection layers 150 may include about 96 wt % to about 99 wt % of Sn. The metal protection layers 150 may include tin-silver-copper (SAC)-based solder alloys. The hardness of the metal protection layers 150 may be greater than that of the first connection terminals 140. The tensile strength of the metal protection layers 150 may be greater than the tensile strength of the first connection terminals 140.

In some embodiments, when metal compound layers (e.g., metal compound layers 145 in FIG. 6) are formed on the surfaces of the first connection terminals 140, the metal protection layers 150 may be formed to cover the metal compound layers 145 on the first connection terminals 140. For example, as illustrated in FIG. 6, the metal compound layers 145 may be covered by the metal protection layers 150, and may not be exposed to the outside. The metal compound layers 145 may be arranged between the metal protection layers 150 and the first connection terminals 140.

The reflectance of each of the metal protection layers 150 and the reflectance of each of the first connection terminals 140 may be less than the reflectance of each of the metal compound layers 145. For example, when the same light is incident, each of the metal protection layers 150 may reflect less amount of light than each of the metal compound layers 145.

In some embodiments, by using a sputtering process, the metal protection layers 150 may be formed on the surfaces of the first connection terminals 140. In some embodiments, the metal protection layers 150 may be conformally formed on the exposed surfaces of the first connection terminals 140. In some embodiments, the thickness of the metal protection layers 150a may become greater away from the first passivation layer 130_P.

FIG. 12F illustrates the operation S150 of removing the protection layer PL in FIG. 11. Referring to FIG. 12F, the protection layer PL may be removed from the base layer 110.

In some embodiments, by irradiating ultraviolet rays to the protection layer PL to weaken the adhesion force of the protection layer PL, the protection layer PL may be removed from the first passivation layer 130_P without damaging the first passivation layer 130_P and the first connection terminals 140.

In some embodiments, when the protection layer PL is in contact with portions of the side surfaces of each of the first connection terminals 140, and the protection layer PL is removed from the first passivation layer 130_P, as illustrated in FIG. 4, the gap G may be formed between each of the metal protection layers 150 and the first passivation layer 130_P.

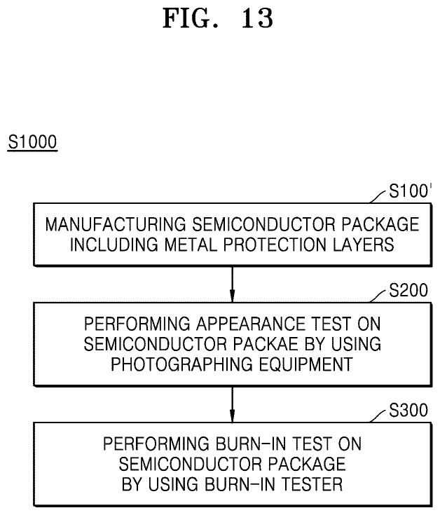

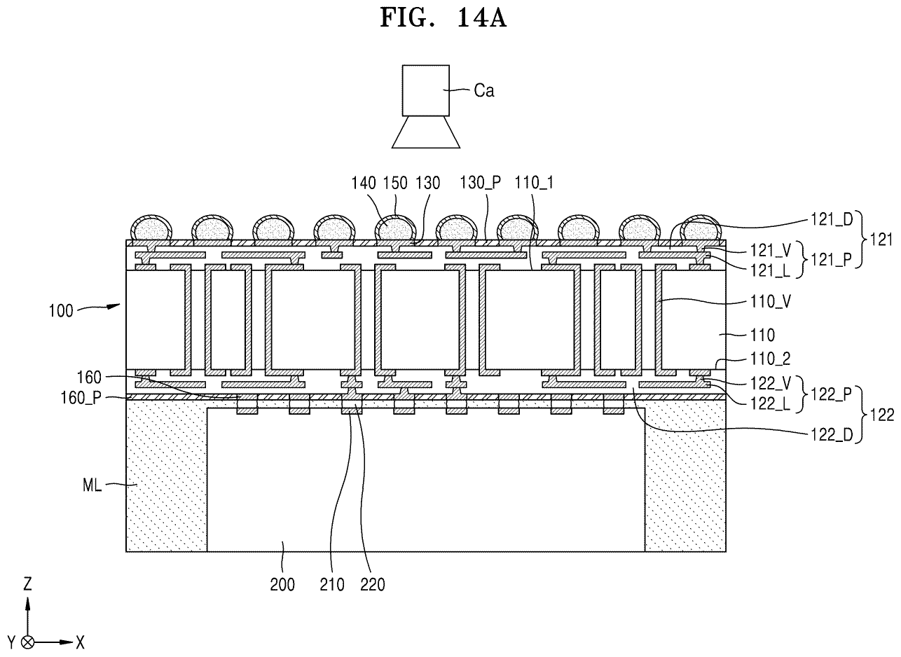

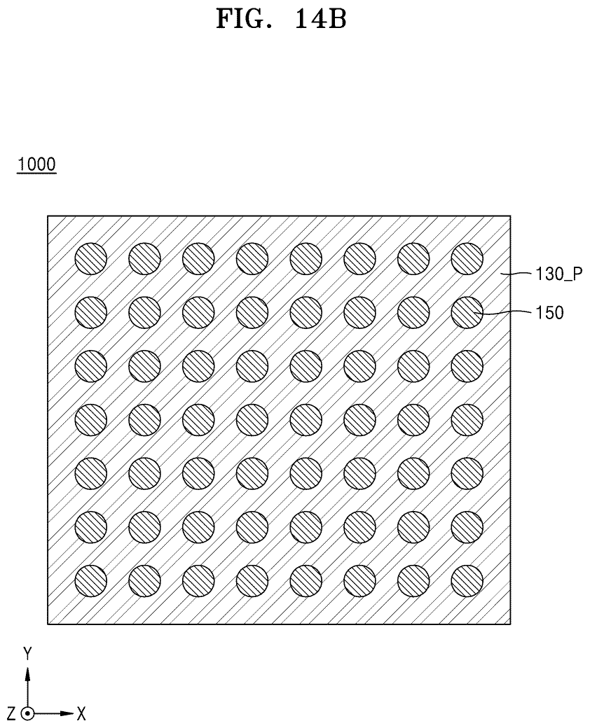

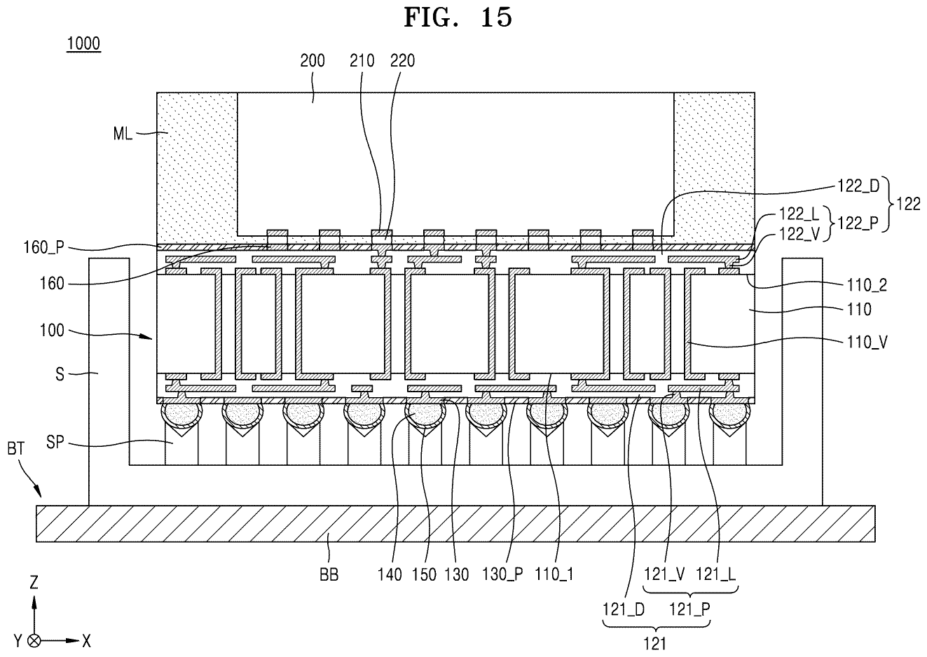

FIG. 13 is a schematic flowchart of processes of a test method S1000 of a semiconductor package, according to an embodiment. FIGS. 14A through 14F are diagrams illustrating portions of the test method S1000 of a semiconductor package, according to embodiments. FIG. 15 is a cross-sectional view illustrating a portion of the test method S1000 of a semiconductor package, according to embodiments.

Referring to FIG. 13, the test method S1000 of a semiconductor package may include an operation S100′ of manufacturing the semiconductor package 1000 including the metal protection layers 150, an operation S200 of performing the appearance test on the semiconductor package 1000 by using a photographing equipment Ca (e.g., a sensor such as, for example, a camera), and an operation S300 of performing the burn-in test on the semiconductor package 1000 by using a burn-in tester BT.

The operation S100′ of manufacturing the semiconductor package 1000 including metal protection layers 150 may include an operation of manufacturing the semiconductor package 1000 according to the manufacturing method S100 of a semiconductor package described above with reference to FIGS. 12A through 12F.

FIGS. 14A and 14B illustrate the operation S200 of performing the appearance test on the semiconductor package 1000 by using the photographing equipment Ca in FIG. 13. Referring to FIGS. 14A and 14B, the appearance test of the semiconductor package 1000 may be performed. For example, an exterior of the semiconductor package 1000 may be photographed by using the photographing equipment Ca, and whether the semiconductor package 1000 is abnormal may be identified. For example, the photographing equipment Ca may include a portion of an auto vision (AVI) system.

In some embodiments, the photographing equipment Ca may photograph the first connection terminals 140 of the semiconductor package 1000. For example, by photographing a lower portion of the semiconductor package 1000, whether the first connection terminals 140 are dropped or omitted from the first bump pads 130 may be identified. The photographing equipment Ca may photograph the first connection terminals 140 arranged on the first surface 110_1 of the base layer 110 of the semiconductor package 1000. Thereafter, whether the first connection terminals 140 are attached to the first bump pads 130 may be identified by using a photograph taken by the photographing equipment Ca.

Referring to FIG. 6, the first connection terminals 140 and the first bump pads 130 having relatively low melting points may chemically react with each other, and the metal compound layers 145 may be formed on the surfaces of the first connection terminals 140. Accordingly, in the absence of the metal protection layers 150, the metal compound layers 145 may be photographed by using the photographing equipment Ca. The metal compound layers 145 may have a higher reflectance than the reflectance of the metal protection layers 150 and the first connection terminals 140.

For example, the photographing equipment Ca may determine positions, where the metal compound layers 145 are photographed by a large amount of light reflected by the metal compound layers 145, as positions where the first connection terminals 140 are not attached, and may determine the semiconductor package 1000, to which the first connection terminals 140 are normally attached, as a defective product. Accordingly, when the appearance test is performed on a semiconductor package of a comparative embodiment in which the metal protection layers 150 are not formed, due to the metal compound layers 145, it may be difficult to identify whether the first connection terminals 140 are respectively and normally attached to the first bump pads 130.

In the case of the semiconductor package 1000 including the metal protection layers 150 having a less reflectance than the metal compound layers 145, the metal compound layers 145 may be covered by the metal protection layers 150 and may not be exposed to the outside. Accordingly, even when the exterior of the semiconductor package 1000 is photographed by using the photographing equipment Ca, the metal protection layers 150 may reflect relatively little light, and accordingly, whether the first connection terminals 140 are normally attached to the first bump pads 130 may be identified. Thus, the reliability of the appearance test on the semiconductor package 1000 may be improved by using the metal protection layers 150.

FIG. 15 illustrates the operation S300 of performing the burn-in test on the semiconductor package 1000 by using the burn-in tester BT. The burn-in test may test the performance of the semiconductor package 1000 in a high temperature situation. For example, the test temperature at which the burn-in test is performed may be about 125 degrees Celsius.

The burn-in tester BT may include a burn-in board BB, and a socket S mounted on the burn-in board BB and including the semiconductor package 1000 mounted thereon. When the semiconductor package 1000 is mounted on the socket S, the socket S may include pins SP electrically connected to the semiconductor package 1000. However, the socket S may include pogo-pins or clamps instead of the pins SP.

In the case of a semiconductor package of a comparative embodiment without the metal protection layers 150, the first connection terminals 140 having a relatively lower melting point may be in direct contact with the socket S. Accordingly, some of the first connection terminals 140 may be melted at the test temperature at which the burn-in test is performed, and may contaminate the socket S.

In the semiconductor package 1000 of an embodiment of the present disclosure, the first connection terminals 140 may be inside the metal protection layers 150 having a melting point higher than the melting point of the first connection terminals 140, and thus the first connection terminals 140 may not be in direct contact with the socket S. Accordingly, even when the first connection terminals 140 are melted, the contamination phenomenon of the socket S may be suppressed.

In the case of a semiconductor package of a comparative embodiment without the metal protection layers 150, the first connection terminals 140 which is soft due to relatively low hardness and tensile strength maybe in direct contact with the pins SP of the socket S. Accordingly, while the burn-in test is in progress, cracks and scratches may occur on the surfaces of the first connection terminals 140.

In the semiconductor package 1000 of an embodiment of the present disclosure, the metal protection layers 150 which is relatively harder than the first connection terminals 140 due to higher hardness and tensile strength may surround the first connection terminals 140, and may suppress and prevent occurrence of scratches and cracks in the first connection terminals 140. Because fewer scratches and cracks occur on the surfaces of the metal protection layers 150 which are relatively harder than the first connection terminals 140, when the semiconductor package 1000 is attached to an external device, the reliability of the semiconductor package 1000 may be improved.

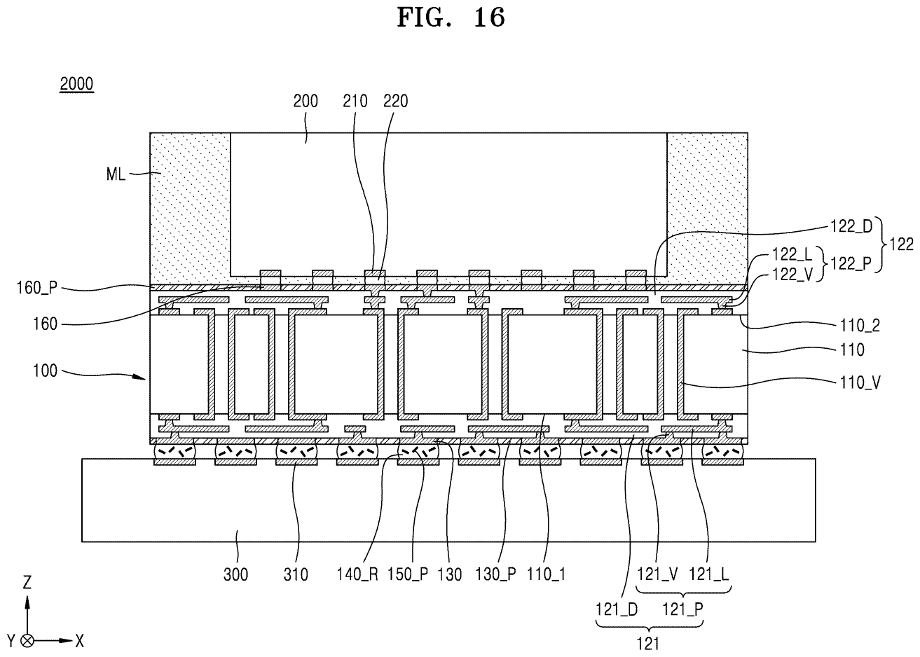

FIG. 16 is a cross-sectional view of a semiconductor package 2000 according to an embodiment.

Referring to FIG. 16, the semiconductor package 2000 may include the package substrate 100, a main substrate 300 configured to mount the package substrate 100, the semiconductor chip 200 configured to be mounted on the package substrate 100, and the molding layer ML.

The semiconductor package 2000 may further include substrate connection terminals 140_R electrically and physically connecting the package substrate 100 to the main substrate 300, metal protection layer fragments 150_P arranged inside the substrate connection terminals 140_R, and chip connection terminals 220 electrically and physically connecting the package substrate 100 to the semiconductor chip 200.

The main substrate 300 may include an external device on which the package substrate 100 is mounted. The main substrate 300 may include substrate bump pads 310 at (e.g., in or on) an upper surface thereof, and may further include an internal distribution electrically connecting the substrate bump pads 310. For example, various semiconductor devices other than the package substrate 100 may be mounted on the main substrate 300. The main substrate 300 may electrically connect the package substrate 100 to the semiconductor device(s), which are mounted on the main substrate 300.

The package substrate 100 arranged on the upper surface of the main substrate 300 may include the base layer 110, the first distribution structure 121, the second distribution structure 122, the through via 110_V, the first bump pads 130, the second bump pads 160, the first passivation layer 130_P, and the second passivation layer 160_P.

Most of the components of the package substrate 100 and the material constituting the components may be substantially the same as or similar to those described above. Thus, for convenience of description, duplicate descriptions may not be repeated.

The substrate connection terminals 140_R may be arranged between the substrate bump pads 310 of the main substrate 300 and the first bump pads 130 of the package substrate 100. In some embodiments, the metal protection layer fragments 150_P may be arranged in the substrate connection terminals 140_R.

The melting point of each of the metal protection layer fragments 150_P may be higher than the melting point of each of the substrate connection terminals 140_R. The tensile strength and hardness of each of the metal protection layer fragments 150_P may be greater than those of each of the substrate connection terminals 140_R. For example, each of the substrate connection terminals 140_R may include about 30 wt % to about 60 wt % of Sn, and each of the metal protection layer fragments may include about 95 wt % to about 99 wt % of Sn.

After a low melting point solder paste is applied onto the substrate bump pads 310 of the main substrate 300, heat may be applied to the package substrate 100 on which the first connection terminals (e.g., first connection terminals 140 in FIG. 1) and the metal protection layers (e.g., metal protection layers 150 in FIG. 1) are formed, and the package substrate 100 may be attached onto the main substrate 300. For example, by applying a reflow process, the low melting point solder paste on the substrate bump pads 310 of the main substrate 300, the first connection terminals and the metal protection layers of the package substrate 100 may be fused to each other. The low melting point solder paste, the first connection terminals, and the metal protection layers, which are fused, may be referred to as the substrate connection terminals 140_R.

For example, in the process of applying heat to the package substrate 100, the metal protection layers (e.g., metal protection layers 150 in FIG. 1) may diffuse, melt, and disappear into the first connection terminals (e.g., first connection terminals 140 in FIG. 1). However, embodiment of the present disclosure are not limited thereto, and in some embodiments, some of the metal protection layers may not be diffused with the first connection terminal to maintain their shape, and thus may become the metal protection layer fragments 150_P.

The semiconductor chip 200 may be on the second distribution structure 122 of the package substrate 100. Chip connection terminals 220 may be arranged between the semiconductor chip 200 and the package substrate 100. Each of the chip connection terminals 220 may be arranged between the second bump pads 160 of the package substrate 100 and the chip pads 210 of the semiconductor chip 200.

In some embodiments, the weight ratio of Sn included in each of the chip connection terminals 220 may be less than the weight ratio of Sn included in each of the substrate connection terminals 140_R.

The molding layer ML may be arranged on the package substrate 100, and may surround the semiconductor chip 200. The side surfaces of the molding layer ML may be aligned with (e.g., coplanar) the side surfaces of the base layer 110 of the package substrate 100 in the vertical direction (e.g., Z direction). The upper surface of the molding layer ML may be coplanar with the upper surface of the semiconductor chip 200. For example, the upper surface of the semiconductor chip 200 may be exposed to the outside.

While non-limiting example embodiments of the present disclosure have been described with reference to the accompanying drawings, it will be understood that various change in form and details may be made therein without departing from the spirit and scope of the present disclosure.

What is claimed is:

1. A package substrate comprising:
a base layer comprising a first surface and a second surface opposite to the first surface;
a through via extending from the first surface of the base layer to the second surface of the base layer;
a first distribution structure on the first surface of the base layer, and comprising a first distribution pattern and a first interlayer insulating layer that surrounds the first distribution pattern;
a first bump pad on and connected to the first distribution pattern of the first distribution structure, the first bump pad spaced apart from the base layer with the first distribution structure between the first bump pad and the base layer;
a first passivation layer on the first distribution structure and surrounding the first bump pad, the first passivation layer comprising an openings that overlaps the first bump pad in a vertical direction;
a first connection terminal in the opening of the first passivation layer and on the first bump pad, the first connection terminal comprising tin(Sn) and having a melting point at a first temperature; and
a metal protection layer on a surface of the first connection terminal, the metal protection layer comprising Sn and having a melting point at a second temperature,
wherein the first temperature is lower than the second temperature.

2. The package substrate of claim 1, wherein the first connection terminal has a first hardness, and
wherein he metal protection layer has a second hardness greater than the first hardness.

3. The package substrate of claim 1, wherein the first connection terminal has a first tensile strength, and
wherein the metal protection layer has a second tensile strength greater than the first tensile strength.

4. The package substrate of claim 1, wherein the first connection terminal comprises 30 wt % to 60 wt % of tin, and
wherein the metal protection layer comprises 95 wt % to 99 wt % of tin.

5. The package substrate of claim 1, wherein the metal protection layer has a thickness of 3 μm to 10 μm.

6. The package substrate of claim 5, wherein the first connection terminal has a maximum width of 100 μm to 600 μm.

7. The package substrate of claim 1, wherein the metal protection layer is conformally arranged on a surface of the first connection terminal that is not in contact with the first bump pad or the first passivation layer.

8. The package substrate of claim 1, wherein a thickness of the metal protection layer increases in a direction away from the first passivation layer.

9. The package substrate of claim 1, wherein the metal protection layer is apart from the first bump pad in the vertical direction, with a gap between the metal protection layer and the first bump pad in the vertical direction, and
wherein a portion of the first connection terminal is exposed to the outside via the gap.

10. The package substrate of claim 9, wherein a thickness of the metal protection layer increases in a direction away from the first passivation layer.

11. The package substrate of claim 1, wherein the first temperature is 140 degrees Celsius to 180 degrees Celsius, and
wherein the second temperature is 200 degrees Celsius to 240 degrees Celsius.

12. The package substrate of claim 1, wherein a width of the opening of the first passivation layer is less than a horizontal width of the first bump pad, and
wherein a sidewall of the first passivation layer define the opening, and the sidewall is in contact with the first connection terminal.

13. A package substrate comprising:
a base layer comprising a first surface and a second surface opposite to the first surface;
a through via extending from the first surface of the base layer to the second surface of the base layer;
a first distribution structure on the first surface of the base layer, and comprising a first distribution pattern and a first interlayer insulating layer surrounding the first distribution pattern;
a first bump pad on and connected to the first distribution pattern of the first distribution structure, the first bump pad spaced apart from the base layer with the first distribution structure between the first bump pad and the base layer;
a first passivation layer on the first distribution structure and surrounding the first bump pad, the first passivation layer including an opening that overlaps with the first bump pad in a vertical direction;
a first connection terminal in the opening of the first passivation layer and on the first bump pad, the first connection terminal comprising tin(Sn) and having a first hardness;
a metal compound layer on a surface of the first connection terminal; and
a metal protection layer on a surface of the first connection terminal and the metal compound layer, and having a second hardness greater than the first hardness,
wherein a melting point of the first bump pad is lower than a melting point of the metal protection layer.

14. The package substrate of claim 13, wherein a reflectance of the metal protection layer is less than a reflectance of the metal compound layer.

15. The package substrate of claim 13, wherein the metal compound layer is between the first connection terminal and the metal protection layer.

16. The package substrate of claim 15, wherein the metal protection layer is on the metal compound layer such that the metal compound layer is not exposed to an outside.

17. The package substrate of claim 13, wherein the metal protection layer is apart from the first bump pad in the vertical direction, with a gap between the metal protection layer and the first bump pad in the vertical direction, and
wherein a portion of the first connection terminal is exposed to the outside via the gap.

18. The package substrate of claim 17, wherein a portion of the metal compound layer is exposed to the outside via the gap.

19. The package substrate of claim 13, wherein a portion of a surface of the first connection terminal, that is not in contact with the base layer is edged.

20. A semiconductor package comprising:
a package substrate comprising:
a base layer comprising a first surface and a second surface opposite to the first surface;
a first distribution structure on the first surface of the base layer;
a second distribution structure on the second surface of the base layer;
a through via that penetrates the base layer and connects the first distribution structure to the second distribution structure;
a first bump pad under a lower surface of the first distribution structure;
a second bump pad on an upper surface of the second distribution structure; and
a first passivation layer that surrounds the first bump pad and includes an opening that overlaps with the first bump pad in a vertical direction;
a main substrate, wherein the package substrate is on an upper surface of the main substrate, and the main substrate comprises a substrate bump pad at the upper surface of the main substrate;
a substrate connection terminal between the package substrate and the main substrate, and configured to electrically, physically, and respectively connect the first bump pad of the package substrate to the substrate bump pad of the main substrate, the substrate connection terminal having a melting point at a first temperature;
metal protection fragments inside the substrate connection terminal, and having a melting point at a second temperature that is higher than the first temperature;
a semiconductor chip on an upper surface of the second distribution structure of the package substrate;
a chip connection terminal between the package substrate and the semiconductor chip, and configured to electrically, physically, and respectively connect the second bump pad of the package substrate to chip pad of the semiconductor chip; and
a molding layer on the package substrate and surrounding the semiconductor chip.
